(19) United States
(12) Patent Application Publication
(10) Pub. No.: US 2026/0091973 A1
(43) Pub. Date: Apr. 2, 2026

(54) High-Vacuum Micro-Vacuum Cells

(71) Applicant: HRL Laboratories, LLC, Malibu, CA (US)

(72) Inventors: Travis M. Autry, Malibu, CA (US); Lian X. Huang, Malibu, CA (US); Mitchel A. Button, Malibu, CA (US); Peter D. Brewer, Malibu, CA (US); John A. Carlson, Malibu, CA (US)

(73) Assignee: HRL Laboratories, LLC, Malibu, CA (US)

(21) Appl. No.: 18/904,886

(22) Filed: Oct. 2, 2024

(51) Int. Cl. B81B 7/00; B81C 1/00

(52) U.S. Cl. CPC B81B 7/0038; B81C 1/00285; B81C 2203/019

(57) ABSTRACT

A micro-vacuum cell comprising at least one vacuum enclosure, the vacuum enclosure comprising at least a lid of a first material, the first material having a first coefficient of thermal expansion; a base of a second material, the second material having a second coefficient of thermal expansion, where the vacuum enclosure is formed above a portion of the base; and a cold weld compression seal attaching the lid to the base along a periphery of said portion of the base; wherein one of the first and second coefficients of thermal expansion is at least five times larger than the other of the first and second coefficients of thermal expansion; and wherein the pressure in the vacuum enclosure is smaller than an atmosphere.

### TECHNICAL FIELD

This presentation relates to Micro-Vacuum Cells (MVC) for Micro-Electro Mechanical Systems (MEMS) and Chip-Scale Atomic Systems (CSAS), in particular to apparatuses comprising a vacuum enclosure. This presentation also relates to methods of manufacturing such micro-vacuum cells or apparatuses.

### BACKGROUND

MVC (Micro-Vacuum Cells) comprise very small devices incorporating some combination of atomic, electronic, and moving parts. MVCs may contain MEMS or CSAS sensors or devices (micro-mirrors, mechanical oscillators, ion-traps, mass spectrometers, or thermal gasses of atoms) having a size of the order of a micrometer. MVC may comprise a processing unit that processes data (for example an integrated circuit chip such as a microprocessor) and at least one component that interacts with the processing unit. Due to their sensitivity to the ambient environment, the MEMS and CSAS devices are generally enclosed in a vacuum enclosure, preferably with a high degree of vacuum for high quality and performance, thus making the MEMS and CSAS part of a MVC.

MEMS and CSAC devices having high vacuum enclosures are for example required for a variety of navigation and timing devices that includes gyroscopes, quartz oscillators, integrated photonic devices, optical cavities, quantum sensors and atomic clocks. It is known to manufacture MVC vacuum enclosures using anodic, eutectic and thermocompression bonding of die and wafer level packages. However, an anodic bonding process releases undesirable gasses such as O₂ which contaminates the inside of the vacuum enclosure. Eutetic, thermocompression, glass-frit, diffusion, and anodic bonding generally require bonding at high temperatures (hereafter a temperature >250 C) where material outgassing becomes a problem during the bonding process by also contaminating the inside of the vacuum enclosure. It is known to provide the inside of a vacuum enclosure with a getter, however at high bonding temperatures, non-evaporable getters can become activated and/or saturated due to the material outgassing. This prevents the getters from lowering and/or maintaining the vacuum pressure at <1E-6 mbar in the MVC vacuum enclosure over an extended period due to finite sorption capacity of the getters.

Another problem of high temperature bonding is that it requires assembling only materials with similar coefficients of thermal expansion. An exception to this is indium bonding due to the strength and malleability of indium. However, indium bonding does not provide a leak rate low enough to maintain vacuum efficiently in a vacuum enclosure. A high leak rate necessitates either an active vacuum pump, or limits the lifetime and base pressure of a MVC.

In the past, the high bonding temperature has limited the bonding to between materials with similar coefficient of thermal expansion. This has resulted in specialty glasses being designed such as the material commercially known as “Hoya SD2 Aluminosilicate” that matches the coefficient of thermal expansion of silicon. However, glass materials are prone to helium permeation, thus limiting the ambient pressure to ˜5 millibar (the partial pressure of helium in atmosphere). The realization of MVCs that can use materials of different Coefficients of Thermal Expansion (CTE) would open up the possibility of using low Helium permeation materials, such as single crystalline sapphire, to form vacuum cells.

The prior art comprises the following references:

Karlen, Sylvain, Jacques Haesler, Thomas Overstolz, Giovanni Bergonzi, and Steve Lecomte. 2020. “Sealing of MEMS Atomic Vapor Cells Using Cu-Cu Thermocompression Bonding.” Journal of Microelectromechanical Systems 29 (1): 95-99. https://doi.org/10.1109/JMEMS.2019.2949349.

Wang, Yiqun, Yaning Wu, Xianhai Xia, Minwei Jiang, Yu Han, Limin Zou, and Peng Jin. 2019. “Micro-Fabricated Alkali Vapor Cells Sealed at Low Temperature Using Asymmetric Au—In Transient Liquid Phase (TLP) Bonding.” Japanese Journal of Applied Physics 58 (SD): SDDL03. https://doi.org/10.7567/1347-4065/ab0ac9.

Pétremand, Y., C. Schori, R. Straessle, G. Mileti, N. de Rooij, and P. Thomann. 2010. “Low Temperature Indium-Based Sealing of Microfabricated Alkali Cells for Chip Scale Atomic Clocks.” In EFTF-2010 24th European Frequency and Time Forum, 1-3. hppts://doi.org/10.1109/EFTF.2010.6533683.

Guo, Ping, Hongling Meng, Lin Dan, and Jianye Zhao. 2022. “Low Power Consumption Physics Package for Chip-Scale Atomic Clock through Gold-Tin Eutectic Bonding.” Microsystem Technologies 28 (7): 1601-6. https://doi.org/10.1007/s00542-022-05283-y.

Wang, Xiaojing, Simon J. Bleiker, Mikael Antelius, Göran Stemme, and Frank Niklaus. 2017. “Wafer-Level Vacuum Packaging Enabled by Plastic Deformation and Low-Temperature Welding of Copper Sealing Rings With a Small Footprint.” Journal of Microelectromechanical Systems 26 (2): 357-65. https://doi.org/10.1109/JMEMS.2017.2654510.

Du, Lin, and Mark G. Allen. 2019. “CMOS Compatible Hermetic Packages Based on Localized Fusion Bonding of Fused Silica.” Journal of Microelectromechanical Systems 28 (4): 656-65. https://doi.org/10.1109/JMEMS.2019.2913533.

Sekiguchi, Naota, Takumi Sato, Kiyoshi Ishikawa, and Atsushi Hatakeyama. 2018. “Spectroscopic Study of a Diffusion-Bonded Sapphire Cell for Hot Metal Vapors.” Applied Optics 57 (1): 52-56. https://doi.org/10.1364/AO.57.000052.

Edinger, Pierre, Gaehun Jo, Chris Phong Van Nguyen, Alain Yuji Takabayashi, Carlos Errando-Herranz, Cleitus Antony, Giuseppe Talli, et al. 2023. “Vacuum-Sealed Silicon Photonic MEMS Tunable Ring Resonator with an Independent Control over Coupling and Phase.” Optics Express 31 (4): 6540-51. https://doi.org/10.1364/OE.480219.

Jo, Gaehun, Pierre Edinger, Simon J. Bleiker, Xiaojing Wang, Alain Yuji Takabayashi, Hamed Sattari, Niels Quack, et al. 2022. “Wafer-Level Hermetically Sealed Silicon Photonic MEMS.” Photonics Research 10 (2): A14-21. https://doi.org/10.1364/PRJ.441215.

Quack, Niels, Alain Yuji Takabayashi, Hamed Sattari, Pierre Edinger, Gaehun Jo, Simon J. Bleiker, Carlos Errando-Herranz, et al. 2023. “Integrated Silicon Photonic MEMS.” Microsystems & Nanoengineering 9 (1): 1-22. https://doi.org/10.1038/s41378-023-00498-z.

There exists a need for a MVC having a vacuum enclosure formed of at least two materials having different CTEs.

### SUMMARY

Embodiments of this presentation comprise a MVC with a vacuum enclosure that is formed using two elements having substantially different CTEs, as well as a method for manufacturing same.

Embodiments of this presentation comprise notably a MVC with high-vacuum cavities, where a first portion of the cavity is made of a material out of which it is easy to manufacture a MVC, such as Si, and where a second portion of the cavity is made out of a crystalline material with low helium permeation, even though the CTEs of these two materials are substantially different. In this presentation, “substantially different” CTEs means CTEs having a ratio of at least 5; preferably 7; preferably 10; preferably 20; preferably larger than 20.

Embodiments of this presentation comprise a method for realizing low-leak rate hermetic bonds at room temperature between different materials such as silicon, sapphire, fused silica, the material known under the commercial name of BOROFLOAT®, GaN, silicon carbide or any other semiconductor or ceramic material.

Embodiments of this presentation comprise a method for reducing the gas load on non-evaporable getters during the material bonding process.

Embodiments of this presentation comprise a method for bonding different CTE materials together using metal.

Embodiments of this presentation comprise a method for extending the lifetime of MVCs by lowering the number of adsorbed molecules on the getters during the bonding process.

Embodiments of this presentation comprise a method for activating the getters after bonding.

Embodiments of this presentation comprise a micro-vacuum cell having at least one vacuum enclosure, the vacuum enclosure comprising at least: a lid of a first material, the first material having a first coefficient of thermal expansion; a base of a second material, the second material having a second coefficient of thermal expansion, where the vacuum enclosure is formed above a portion of the base; and a cold weld compression seal attaching the lid to the base along a periphery of said portion of the base; wherein one of the first and second coefficients of thermal expansion is at least five times larger than the other of the first and second coefficients of thermal expansion; and wherein the pressure in the vacuum enclosure is smaller than an atmosphere.

According to embodiments of this presentation, said portion of the base comprises a recess, said recess forming part of the vacuum enclosure.

According to embodiments of this presentation, a getter is arranged on an inside portion of the vacuum enclosure.

According to embodiments of this presentation, at least one of the lid and the base is transparent to a light wavelength, wherein the getter can be activated by said light wavelength.

According to embodiments of this presentation, a micro-electromechanical structure is arranged in the vacuum enclosure.

According to embodiments of this presentation, one of the first and second coefficients of thermal expansion is at least ten times larger than the other of the first and second coefficients of thermal expansion; preferably one of the first and second coefficients of thermal expansion is at least twenty times larger than the other of the first and second coefficients of thermal expansion.

According to embodiments of this presentation, the pressure in the vacuum enclosure is smaller than a millitorr.

According to embodiments of this presentation, the cold weld compression seal comprises a peripheral knife-edge wall of a harder metal having a foot attached to one of the lid and the base, said knife-edge wall being coated with a softer metal before being pressed on a peripheral layer of another softer metal arranged on the other of the lid and the base.

According to embodiments of this presentation, the harder metal is titanium and the softer metals are both gold.

According to embodiments of this presentation, the materials of the lid and base are selected among silicon, glass (lime glass or fused silica), sapphire, alumina, SiC, AlN, GaAs, GaN and any other semiconductor or ceramic substrate.

Other embodiments of this presentation include a method of manufacturing a micro-vacuum cell comprising at least one vacuum enclosure, the method comprising: providing a lid of a first material, the first material having a first coefficient of thermal expansion; providing a base of a second material, the second material having a second coefficient of thermal expansion, where the vacuum enclosure is to be formed above a portion of the base; forming around said portion of the base a first part of a cold weld compression seal, and forming on a surface of the lid a corresponding second part of said cold weld compression seal; baking the lid and the base under vacuum for a predetermined time; without breaking the vacuum, letting the lid and the base cool down, then align the first and second parts of the cold weld compression seal and press them together until a predetermined pressure is reached; wherein one of the first and second coefficients of thermal expansion is at least five times larger than the other of the first and second coefficients of thermal expansion; and wherein the pressure in the vacuum enclosure is smaller than an atmosphere.

According to embodiments of this presentation, the method further comprises forming a recess in said portion of the base, such that said recess forms part of the vacuum enclosure.

According to embodiments of this presentation, the method further comprises arranging a getter on an inside portion of the vacuum enclosure.

According to embodiments of this presentation, at least one of the lid and the base is transparent to a light wavelength, the method comprising activating the getter using said light wavelength once the cold weld compression seal has been completed.

According to embodiments of this presentation, the method further comprises arranging a micro-electromechanical structure on said portion of the base before baking the base, so that said micro-electromechanical structure is arranged in the vacuum enclosure.

According to embodiments of this presentation, one of the first and second coefficients of thermal expansion is at least ten times larger than the other of the first and second coefficients of thermal expansion; or wherein one of the first and second coefficients of thermal expansion is at least twenty times larger than the other of the first and second coefficients of thermal expansion.

According to embodiments of this presentation, the pressure in the vacuum enclosure is smaller than a millitorr.

According to embodiments of this presentation, one of said first part and said second part of the cold weld compression seal comprises a peripheral knife-edge wall of a harder metal having a foot attached to one of the lid and the base, said knife-edge wall being coated with a softer metal, and the other of said first part and said second part of the cold weld compression seal comprising a peripheral layer of another softer metal arranged on the other of the lid and the base.

According to embodiments of this presentation, the harder metal is titanium and the softer metals are both gold.

According to embodiments of this presentation, the materials of the lid and base are selected among silicon, glass, sapphire and SiC.

### FIGURES

The above features will now be described in more details in relation with the following figures, wherein:

FIG. 1 illustrates a cross section of a MVC according to embodiments of this presentation.

FIGS. 2A to 2H illustrate successive steps of manufacturing of the MVC of FIG. 1.

FIG. 3 illustrates a cross section of a MVC according to other embodiments of this presentation.

FIG. 4 illustrates a wafer having two completed MVCs according to this presentation as well as a number of uncomplete ones.

FIG. 5 is a flow chart illustrating a method according to embodiments of this presentation.

### DETAILED DESCRIPTION

The following description is presented to enable one of ordinary skill in the art to make and use the teachings of this presentation and to incorporate them in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of embodiments of this presentation. However, it will be apparent to one skilled in the art that such embodiments may be practiced without necessarily being limited to these specific details.

All the features disclosed in this presentation, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112(f). In particular, the use of “step of” or “act of” in the claims herein is not intended to invoke the provisions of 35 U.S.C. 112, Paragraph 6 (Pre-AIA).

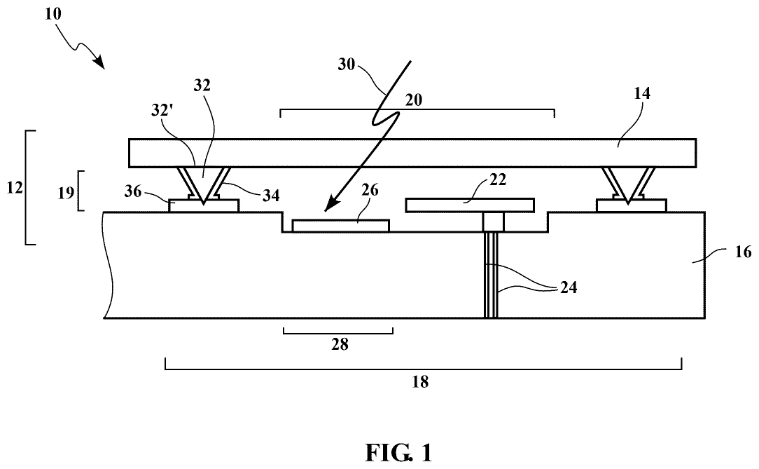

FIG. 1 illustrates a Micro-Vacuum Cell 10, comprising at least one vacuum enclosure 12. The vacuum enclosure 12 comprises at least: a lid 14 of a first material, the first material having a first coefficient of thermal expansion; a base 16 of a second material, the second material having a second coefficient of thermal expansion, where the vacuum enclosure is formed above a portion 18 of the base; and a cold weld compression seal 19 attaching the lid 14 to the base 16 along a periphery of said portion 18 of the base. According to embodiments of this presentation, the material of the lid 14 and the material of the base 16 have a CTE ratio of at least 5; preferably 7; preferably 10; preferably 20; preferably larger than 20; and the pressure in the vacuum enclosure is smaller than an atmosphere; preferably smaller than a milliTorr, preferably smaller than a microTorr, and preferably smaller than 1E-12 Torr (UHV).

According to embodiments of this presentation, the portion 18 of the base comprises a recess 20. The recess 20 forms part of the vacuum enclosure 12 and it provides room for arranging a moving part (or micro-electromechanical structure) 22 in the enclosure 12. Moving part 22 can comprise one or more crystal oscillators, but it can comprise any of one or more micro-mirrors or mechanical oscillators or gravity sensors. As illustrated in FIG. 1, Micro-Vacuum Cell 10 can comprise electrical connections 24 to the moving part 22. The electrical connections 24 are preferably coupled to a control circuit (not illustrated) integrated in base 16. Electrical connections 24 can comprise vias and they are provided such that no leaking of the vacuum of cavity 12 is due to the structure of these connections.

According to embodiments of this presentation, a getter 26 is arranged on an inside portion 28 of the vacuum enclosure 12, for example of the portion 18 of the base. Getter 26 can be a layer of a getter material sputtered on inside portion 28 of enclosure 12. According to embodiments of this presentation, at least one of the lid 14 and the base 16 is transparent to a light having a predetermined wavelength, such that the getter can be activated by a beam 30 of said light. Alternatively, a heating circuit (not shown) can be arranged under the getter for activation.

According to embodiments of this presentation, the cold weld compression seal 19 comprises a peripheral knife-edge wall 32 of a harder metal having a foot 32′ attached to one of the lid 14 and the base 16 (to the lid 14 in FIG. 1), said knife-edge wall 32 being coated 34 with a softer metal before being pressed on a peripheral layer 36 of a metal also softer than wall 32, arranged on the other of the lid and the base (arranged on the periphery of the portion 18 of the base in FIG. 1). Metals 34 and 36 can be a same softer metal or they can be different softer metals. According to embodiments of this presentation, the harder metal is titanium and the softer metal is gold. Other metal combinations include Ti/Cu, Ti/Pd, Ti/Ag, Ti/Al.

According to embodiments of this presentation, the materials of the lid and base are selected among silicon, glass (lime glass or fused silica), sapphire, alumina, SiC, AlN, GaAs, GaN and any other semiconductor or ceramic substrate.

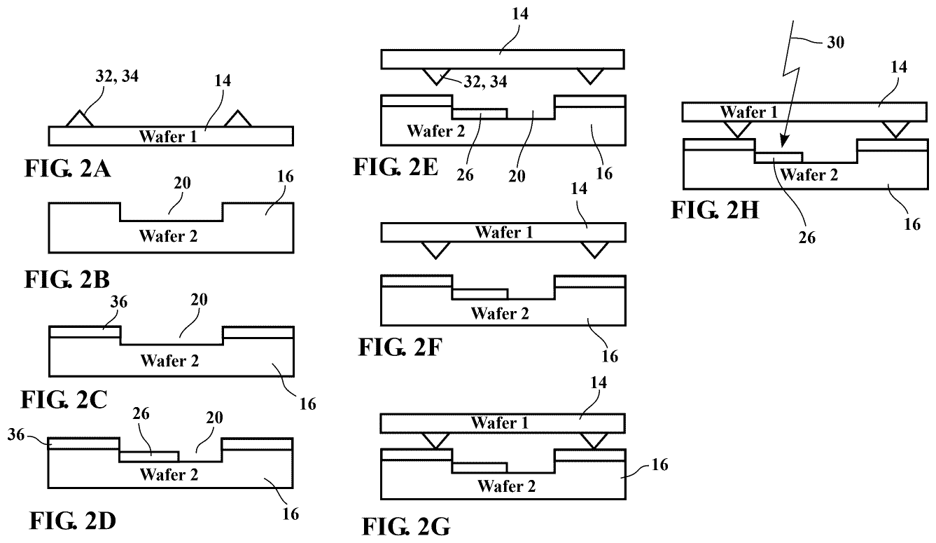

FIGS. 2A to 2H illustrate successive steps of manufacturing of the Micro-Vacuum Cell of FIG. 1. In FIG. 2A, lid 14 with the coated peripheral knife-edge wall 32, 34 is provided. By “peripheral”, it is meant that the wall completely encircles an area of the lid, or is arranged on a periphery of said area. Knife-edge wall 32, 34 can be manufactured using photolithography manufacturing processes.

The width of the foot of the knife-edge wall, as well as its height can be of the order of a few micrometers. The wall can be made of titanium. The wall can be capped by a layer of softer metal, for example gold, for example having a thickness of about 200 nm. All metals can be deposited with e-beam evaporation and a photoresist process.

In FIG. 2B, base 16 having cavity 20 is provided and in FIG. 2C, peripheral layer 36 is added on a periphery of cavity 20. Moving part 22 can be present in cavity 20 at this stage, but is not illustrated for ease of reference. In FIG. 2D, getter 26 is formed in a portion of cavity 20. The cavity can be formed with wet etching, dry-etching, or machining. The peripheral layer 36 can have a thickness of the order of one or more micrometers; for example of gold; it can be made using e-beam evaporation and a photoresist process.

In FIG. 2E, both the lid 14 and the base 16 are baked under vacuum for a predetermined time, for example at 150 degrees Celsius for 12 hours. The baking temperature could vary from 100 C to 350 C. This step removes hydrogen, helium and noble gasses that are in the materials.

In FIG. 2F, without breaking the vacuum, the lid and the base are left to cool down to for example room temperature, before the first and second parts of the cold weld compression seal (the coated knife-edge wall) and the corresponding peripheral layer are aligned and in FIG. 2G they are pressed together until a predetermined pressure is reached, thus sealing the vacuum enclosure 12. Said predetermined pressure can for example be 300 Mpa or more. The small feature size of the wall results in pressures at the knife-edge tip that are much greater than the deformation strength of the knife metal. This results in a cold-weld compression bond that is hermetic.

In FIG. 2H, getter 26 is activated by a beam of light/radiation 30, for example from a high power laser, through lid 14. Activation of the getter 26 allows obtaining a higher level of vacuum in the enclosure 12 than at the time the enclosure 12 is sealed. A hot plate or other heating element can also be used to activate the getter.

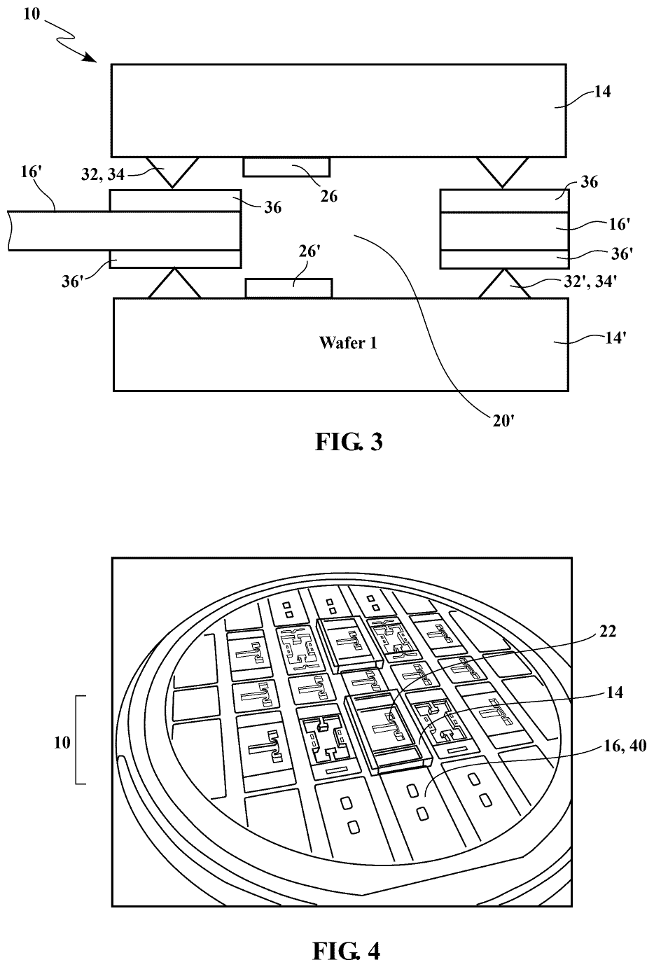

FIG. 3 illustrates a cross section of a MVC 10′ according to other embodiments of this presentation, which is similar to the MVC 10 of FIG. 1, and wherein similar reference numbers relate to similar elements. MVC 10′, instead of having a base 16 with a cavity 20, has a base 16′ with a through-cavity 20′ between a first main surface and a second main surface. In this embodiment, peripheral soft metal layer 36 is arranged on the first main surface of base 16′ on a periphery of cavity 20′. Additionally, a second peripheral soft metal layer 36′ is arranged on the second main surface of base 16′ on a periphery of cavity 20′. A second lid 14′, that can be of the same material as the first lid 14 or that can be of a different material, is attached to base 16′ by a second knife-edge peripheral wall 32′ attached to lid 14′, coated with a soft metal layer 34′, and pressed into said second peripheral soft metal layer 36′ in the same way as wall 32 for fid 14. A getter 26 can be attached to lid 14 inside the vacuum enclosure comprising cavity 20′. A getter 26′ can be attached to lid 14′ inside the vacuum enclosure comprising cavity 20′. A getter (not illustrated) can also be attached to a wall of cavity 20′. Mobile part 22 (not illustrated) can be attached to one of lids 14, 14′ or to a wall of cavity 20′.

Generally speaking, embodiments of this presentation comprise MVCs with vacuum enclosures having multilayer bonds that can comprise more than one base with a through-cavity attached together, for example using cold-weld compression bonds.

FIG. 4 is a picture of a wafer 40 comprising at least one Micro-Vacuum Cell 10, wherein base 16 is a portion of wafer 40. A transparent lid 14 encloses a vacuum cavity wherein a mobile part 22 is arranged. The MVC illustrated in FIG. 4 was manufactured using silicon, fused silica and borosilicate glass. The fused silica was used as part of the cavity layer to hold atoms. It is easy to make high aspect ratio features in fused silica because of selective laser etching.

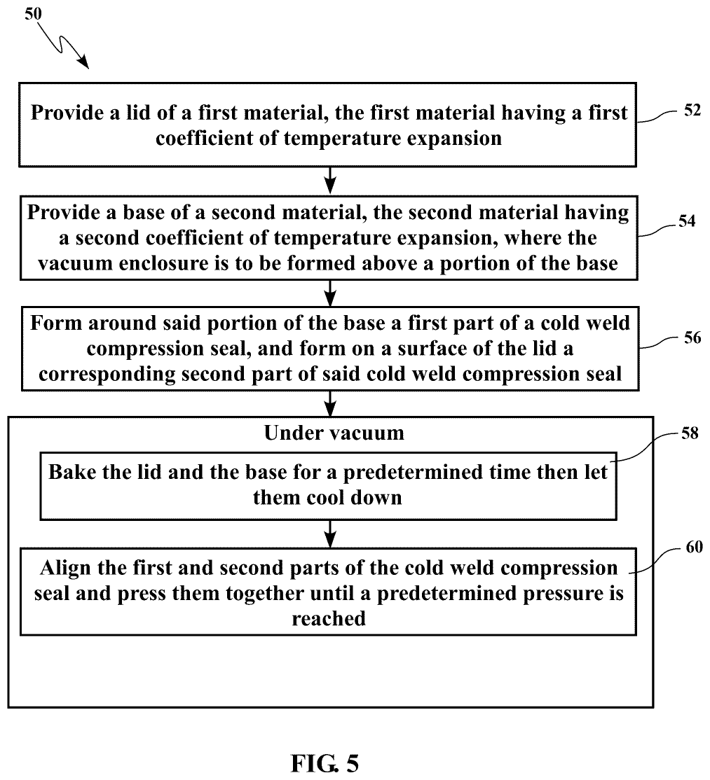

FIG. 5 is a flow chart illustrating a method 50 of manufacturing a micro-electromechanical systems apparatus according to embodiments of this presentation, the method comprising:

Providing 52 a lid of a first material, the first material having a first coefficient of thermal expansion.

Providing 54 a base of a second material, the second material having a second coefficient of thermal expansion, where the vacuum enclosure is to be formed above a portion of the base.

Forming 56 around said portion of the base a first part of a cold weld compression seal, and forming on a surface of the lid a corresponding second part of said cold weld compression seal.

Baking 58 the lid and the base under vacuum for a predetermined time and, without breaking the vacuum, letting the lid and the base cool down, then align 60 the first and second parts of the cold weld compression seal and press them together until a predetermined pressure is reached and the cold weld compression seal sealingly assembles the lid to the base.

According to embodiments of this presentation, the material of the lid 14 and the material of the base 16 have a CTE ratio of at least 5; preferably 7; preferably 10; preferably 20; preferably larger than 20; and the pressure in the vacuum enclosure is smaller than an atmosphere; preferably smaller than 1 milltorr, preferably smaller than one microTorr, preferably smaller than 1E-12 Torr.

According to embodiments of this presentation, said providing 54 a base where the vacuum enclosure is to be formed above a portion of the base comprises forming a recess in said portion of the base, such that said recess forms part of the vacuum enclosure.

According to embodiments of this presentation, said providing 52 a lid and/or said providing 54 a base comprises arranging a getter on the lid or on the base such that the getter ends up on an inside portion of the vacuum enclosure.

According to embodiments of this presentation, said providing 52 a lid and/or said providing 54 a base comprises providing a lid and/or a base that is transparent to a light wavelength capable of activating the getter; the method further comprising activating the getter using said light wavelength once the cold weld compression seal has been completed.

According to embodiments of this presentation, said providing 52 a lid and/or said providing 54 a base comprises arranging a micro-electromechanical structure on the lid or on said portion of the base before baking the base and the lid, such that said micro-electromechanical structure ends up arranged in the vacuum enclosure.

According to embodiments of this presentation, one of said first part and said second part of the cold weld compression seal comprises a peripheral knife-edge wall of a harder metal having a foot attached to one of the lid and the base, said knife-edge wall being coated with a softer metal, and the other of said first part and said second part of the cold weld compression seal comprises a peripheral layer of another softer metal arranged on the other of the lid and the base. According to embodiments of this presentation, the harder metal can be titanium and the softer metals can both be gold. According to embodiments of this presentation, the materials of the lid and base are selected among silicon, glass (lime glass or fused silica), sapphire, alumina, SiC, AlN, GaAs, GaN and any other semiconductor or ceramic substrate.

In other words, according to embodiments of this presentation, a MVC having a vacuum enclosure is fabricated by: baking a base with a recess and (optionally) a non-evaporable getter in the recess, as well as a lid of a size corresponding to the recess, at low temperature ˜150 C for an extended period of time (˜12 hours to days) to remove hydrogen, helium, and noble gasses that may be dissolved within or adsorbed to material surfaces. The base and lid are preferably low helium permeation materials. The lid and the base recess respectively bear on their periphery first and second parts of a cold weld compression seal; the lid and the base are bonded together at room temperature in a high vacuum <1E-6 Torr vacuum environment by pressing together the first and second parts of the cold weld compression seal.

In case a getter is in the cavity, the getter is then activated inside the sealed vacuum enclosure using either heat from an oven or, if the lid or the base is optically transparent, a high-power optical source can be used to heat and activate the non-evaporable getters.

Optionally, chemically active getters such as alkali atoms can be used for additional vacuum pumping.

Having now described the invention in accordance with the requirements of the patent statutes, those skilled in this art will understand how to make changes and modifications to the present invention to meet their specific requirements or conditions. Such changes and modifications may be made without departing from the scope and spirit of the invention as disclosed herein.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom.

Applicant has made this disclosure with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112(f), unless the element is expressly recited using the phrase “means for . . . ” and no method or process step herein is to be construed under those provisions unless the step, or steps, are expressly recited using the phrase “comprising the step(s) of . . . ”

All elements, parts and steps described herein are preferably included. It is to be understood that any of these elements, parts and steps may be replaced by other elements, parts and steps or deleted altogether as will be obvious to those skilled in the art.

What is claimed is:

1. A micro-vacuum cell comprising at least one vacuum enclosure, the vacuum enclosure comprising at least:
a lid of a first material, the first material having a first coefficient of thermal expansion;
a base of a second material, the second material having a second coefficient of thermal expansion, where the vacuum enclosure is formed above a portion of the base; and
a cold weld compression seal attaching the lid to the base along a periphery of said portion of the base;
wherein one of the first and second coefficients of thermal expansion is at least five times larger than the other of the first and second coefficients of thermal expansion; and
wherein the pressure in the vacuum enclosure is smaller than an atmosphere.

2. The micro-vacuum cell of claim 1, wherein said portion of the base comprises a recess, said recess forming part of the vacuum enclosure.

3. The micro-vacuum cell of claim 1, wherein a getter is arranged on an inside portion of the vacuum enclosure.

4. The micro-vacuum cell of claim 3, wherein at least one of the lid and the base is transparent to a light wavelength, wherein the getter can be activated by said light wavelength.

5. The micro-vacuum cell of claim 1, wherein a micro-electromechanical structure is arranged in the vacuum enclosure.

6. The micro-vacuum cell of claim 1, wherein one of the first and second coefficients of thermal expansion is at least ten times larger than the other of the first and second coefficients of thermal expansion; or wherein one of the first and second coefficients of thermal expansion is at least twenty times larger than the other of the first and second coefficients of thermal expansion.

7. The micro-vacuum cell of claim 1, wherein the pressure in the vacuum enclosure is smaller than a millitorr.

8. The micro-vacuum cell of claim 1, wherein the cold weld compression seal comprises a peripheral knife-edge wall of a harder metal having a foot attached to one of the lid and the base, said knife-edge wall being coated with a softer metal before being pressed on a peripheral layer of another softer metal arranged on the other of the lid and the base.

9. The micro-vacuum cell of claim 8, wherein the harder metal is titanium and the softer metals are both gold.

10. The micro-vacuum cell of claim 1, wherein the materials of the lid and base are selected among silicon, glass (lime glass or fused silica), sapphire, alumina, SiC, AlN, GaAs, GaN and any other semiconductor or ceramic substrate.

11. A method of manufacturing a micro-vacuum cell comprising at least one vacuum enclosure, the method comprising:
providing a lid of a first material, the first material having a first coefficient of thermal expansion;
providing a base of a second material, the second material having a second coefficient of thermal expansion, where the vacuum enclosure is to be formed above a portion of the base;
forming around said portion of the base a first part of a cold weld compression seal, and forming on a surface of the lid a corresponding second part of said cold weld compression seal;
baking the lid and the base under vacuum for a predetermined time;
without breaking the vacuum, letting the lid and the base cool down, then align the first and second parts of the cold weld compression seal and press them together until a predetermined pressure is reached;
wherein one of the first and second coefficients of thermal expansion is at least five (5) times larger than the other of the first and second coefficients of thermal expansion; and
wherein the pressure in the vacuum enclosure is smaller than an atmosphere.

12. The method of claim 11, comprising forming a recess in said portion of the base, such that said recess forms part of the vacuum enclosure.

13. The method of claim 1, comprising arranging a getter on an inside portion of the vacuum enclosure.

14. The method of claim 13, wherein at least one of the lid and the base is transparent to a light wavelength, the method comprising activating the getter using said light wavelength once the cold weld compression seal has been completed.

15. The method of claim 11, comprising arranging a micro-electromechanical structure on said portion of the base before baking the base, so that said micro-electromechanical structure is arranged in the vacuum enclosure.

16. The method of claim 11, wherein one of the first and second coefficients of thermal expansion is at least ten times larger than the other of the first and second coefficients of thermal expansion; or wherein one of the first and second coefficients of thermal expansion is at least twenty times larger than the other of the first and second coefficients of thermal expansion.

17. The method of claim 11, wherein the pressure in the vacuum enclosure is smaller than a millitorr.

18. The method of claim 11, wherein one of said first part and said second part of the cold weld compression seal comprises a peripheral knife-edge wall of a harder metal having a foot attached to one of the lid and the base, said knife-edge wall being coated with a softer metal, and wherein the other of said first part and said second part of the cold weld compression seal comprises a peripheral layer of another softer metal arranged on the other of the lid and the base.

19. The method of claim 18, wherein the harder metal is titanium and the softer metals are both gold.

20. The method of claim 11, wherein the materials of the lid and base are selected among silicon, glass, sapphire and SiC.
